(19) United States
(12) Patent Application Publication
(10) Pub. No.: US 2015/0333775 A1
(43) Pub. Date: Nov. 19, 2015

(54) Frozen-Bit Selection for a Polar Code Decoder

(71) Applicant: Broadcom Corporation, Irvine, CA (US)

(72) Inventors: Matthias KORB, Mission Viejo, CA (US); Andrew BLANKSBY, Lake Oswego, OR (US); Youn Sung PARK, Ann Arbor, MI (US)

(73) Assignee: Broadcom Corporation, Irvine, CA (US)

(21) Appl. No.: 14/482,772

(22) Filed: Sep. 10, 2014

Related U.S. Application Data
(60) Provisional application No. 61/993,796, filed on May 15, 2014.

(51) Int. Cl. H03M 13/45; H03M 13/13

(52) U.S. Cl. CPC H03M 13/458; H03M 13/13

(57) ABSTRACT

The present disclosure is directed to a system and method for decoding a polar encoded codeword using a frozen bit pattern determined based on a frozen bit pattern derived for a trellis decoder with a different routing structure between each of a plurality of processing stages. The frozen bit pattern can be determined based on the frozen bit pattern derived for the trellis decoder with the different routing structure between each of the plurality of processing stages such that a belief propagation decoder that uses a plurality of time-multiplexed processing elements with a fixed routing interconnect can still achieve a high decoding performance.

### CROSS REFERENCE TO RELATED APPLICATIONS

This application claims the benefit of U.S. Provisional Patent Application No. 61/993,796, filed May 15, 2014, which is incorporated by reference herein.

### TECHNICAL FIELD

This application relates generally to polar codes, including decoders for polar encoded codewords.

### BACKGROUND

Linear block codes are a family of error-correcting codes that encode data in blocks. For example, an (N, k) linear block code encodes an information vector u of length k into a codeword vector x of length N by multiplying the information vector u by a generator matrix F. The codeword vector x is then transmitted to a receiver over a communication channel. A decoder at the receiver receives a vector y that represents the codeword vector x with noise picked up from the communication channel. The decoder processes the vector y to produce an estimate u of the original information vector u.

In 2008, a new class of linear block codes were invented called polar codes. Polar codes are the first family of codes that are proven to achieve capacity for symmetric binary-input discrete memoryless channels and are constructed on the basis of a probabilistic phenomenon referred to as “channel polarization.” In general, channel polarization refers to the observation that as the code length N grows large for polar codes, the “channels” seen by individual ones of the bits in an information vector u asymptotically approach either a pure-noise channel or a pure-noiseless channel. The fraction of channels that become noiseless is equal to the capacity of the channel in the limit case. Polar codes are constructed by identifying the indices of the bits in the information vector u that see channels approaching noise free conditions and using those indices (or some subset of those indices) to transmit information, while setting the remaining indices to predetermined values known by both the encoder and decoder. The indices set to predetermined values are referred to as “frozen bits.” One issue with polar codes is determining a good set of frozen bits for channels other than symmetric binary-input discrete memoryless channels, such as other explicit communication channels including the additive white Gaussian noise (AWGN) channel.

The following generator matrix is conventionally used to form a basis for polar codes although other lower triangular generator matrices can be used:

$${F}_{2} = ( \begin{matrix}1 & 0 \\ 1 & 1\end{matrix} ) \qquad ( 1 )$$

Encoding involves applying the transform F₂^{⊕n}, where “^{⊕n}” denotes the nth Kronecker power, to a block of N=2ⁿ bits. An example polar encoder 100 is shown in FIG. 1 for N=8. Polar encoder 100 applies the linear transform F₂^{⊕n} to a source vector u=(u₀, u₁, . . . , u_{N-1}) consisting of k information bits and N−k frozen bits to produce a codeword vector x=(x₀, x₁, . . . , x_{N-1}). In general, polar encoders, such as polar encoder 100, can be divided into n=log₂N processing stages, each with N/2 exclusive OR elements 102 per processing stage. Each bit of the codeword vector x after being produced by encoder 100 is passed to an independent channel, where the channels have been polarized to some degree as described above.

Polar decoding is conventionally performed using the successive cancellation decoding algorithm. The successive cancellation decoding algorithm is similar to the sum-product algorithm and performs a soft estimation of the original information vector u by making use of the equality and parity constraints introduced by the encoder.

FIG. 2 illustrates an example successive cancellation decoder 200 for N=8. A received vector y is processed by a network of parity check elements 202 and equality constraint elements 204 to produce an estimated information vector û. Provided the inputs are expressed as likelihood ratios, the following functions are respectively performed by parity check elements 202 and equality constraint elements 204:

$$\begin{matrix}f ( {l}_{a} , {l}_{b} ) = \frac{1 + {l}_{a} \cdot {l}_{b}}{{l}_{a} + {l}_{b}} & ( 2 ) \\ g ( {l}_{a} , {l}_{b} , \hat{s} ) = {l}_{a} \cdot {l}_{b}^{1 - 2 \cdot \hat{s}} & ( 3 )\end{matrix}$$

It will be appreciated that equivalent functions can be derived in the logarithmic domain and performed by parity check elements 202 and equality constraint elements 204. The equivalent function performed by parity check elements 202 can be further simplified through the use of the min-sum approximation used in low density parity check (LDPC) decoding. The structure of polar decoder 200 can be referred to as a Kronecker-based trellis decoder given that its structure is based on the transform

[symbol]

In general, the successive cancellation decoding algorithm can be implemented with O(N log N) complexity, but due to the inherent data dependencies in the algorithm, very little parallelization can be exploited in implementing the algorithm. As a result, successive cancellation decoders, such as decoder 200 in FIG. 2, suffer from low decoding throughput and high latency.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 illustrates an example polar encoder.

FIG. 2 illustrates an example successive cancellation polar decoder.

FIG. 3 illustrates a flowchart of an example simulated annealing based method for determining a good frozen bit pattern in accordance with embodiments of the present disclosure.

FIG. 4 illustrates a flowchart of an example hill-climbing based method for determining a good frozen bit pattern in accordance with embodiments of the present disclosure.

FIG. 5 illustrates an example belief propagation decoder with a Kronecker-based trellis structure in accordance with embodiments of the present disclosure.

FIG. 6 illustrates an example belief propagation decoder with the same routing structure between stages of processing elements in accordance with embodiments of the present disclosure.

FIG. 7 illustrates an example belief propagation decoder with a time-multiplexed stage of processing elements in accordance with embodiments of the present disclosure.

FIG. 8 illustrates a block diagram of an example computer system that can be used to implement aspects of the present disclosure.

The embodiments of the present disclosure will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of this discussion, the term “module” shall be understood to include software, firmware, or hardware (such as one or more circuits, microchips, processors, and/or devices), or any combination thereof. In addition, it will be understood that each module can include one, or more than one, component within an actual device, and each component that forms a part of the described module can function either cooperatively or independently of any other component forming a part of the module. Conversely, multiple modules described herein can represent a single component within an actual device. Further, components within a module can be in a single device or distributed among multiple devices in a wired or wireless manner.

### I. OVERVIEW

The present disclosure is directed to a system and method for decoding a polar encoded codeword using a frozen bit pattern determined for a communication channel other than a symmetric binary-input discrete memoryless channel, such as other explicit communication channels including the additive white Gaussian noise (AWGN) channel. The frozen bit pattern is determined using a simulated annealing based algorithm or a hill-climbing based algorithm. These two algorithms find a good frozen bit pattern for a given block length and code rate in a reasonable amount of time, where “good” can be defined based on whether the frozen bit pattern provides a coding gain above some predetermined threshold amount. The frozen bit pattern can be used for both successive cancellation decoders and belief propagation decoders.

The present disclosure is further directed to a system and method for decoding a polar encoded codeword using a frozen bit pattern determined based on a frozen bit pattern derived for a trellis decoder with a different routing structure between each of a plurality of processing stages. The frozen bit pattern can be determined based on the frozen bit pattern derived for the trellis decoder with the different routing structure between each of the plurality of processing stages such that a belief propagation decoder that uses a plurality of time-multiplexed processing elements with a fixed routing interconnect can still achieve a high decoding performance.

The systems and methods of the present disclosure can be used in several different types of wireless and wired receivers, including receivers used to communicate over local area networks (e.g., 802.11 and 802.3 receivers), receivers used to perform cellular communication (e.g., a Long Term Evolution and Worldwide Interoperability for Microwave Access receivers), and receivers used to perform short range wireless communication (e.g., Bluetooth® receivers). These and other features of the present disclosure are described further below.

### II. FROZEN BIT PATTERN SELECTION

As mentioned above, polar codes are the first family of codes that are proven to achieve capacity for symmetric binary-input discrete memoryless channels and are constructed on the basis of the probabilistic phenomenon referred to as “channel polarization.” Channel polarization refers to the observation that as the code length N grows large for polar codes, the “channels” seen by individual ones of the bits in an information vector u asymptotically approach either a pure-noise channel or a pure-noiseless channel. The fraction of channels that become noiseless is equal to the capacity of the channel in the limit case.

Polar codes are constructed by identifying the indices of the bits in the information vector u that see channels approaching noise free conditions and using those indices (or some subset of those indices) to transmit information, while setting the remaining indices to predetermined values known by both the encoder and decoder. The indices set to predetermined values are referred to as “frozen bits.” One issue with polar codes is determining a good set of frozen bits for channels other than symmetric binary-input discrete memoryless channels, such as other explicit communication channels including the additive white Gaussian noise (AWGN) channel. In general, determining the optimal set of frozen bits for a given code rate and channel type is a non-deterministic polynomial time (NP) problem.

The present disclosure is directed to a system and method for decoding a polar encoded codeword using a frozen bit pattern determined for a communication channel other than a symmetric binary-input discrete memoryless channel, such as an AWGN channel. Two algorithms are described in turn below for determining such frozen bit patterns. These two algorithms include a simulated annealing based algorithm and a hill-climbing based algorithm. Both algorithms are able to find good frozen bit patterns in reasonable amounts of time.

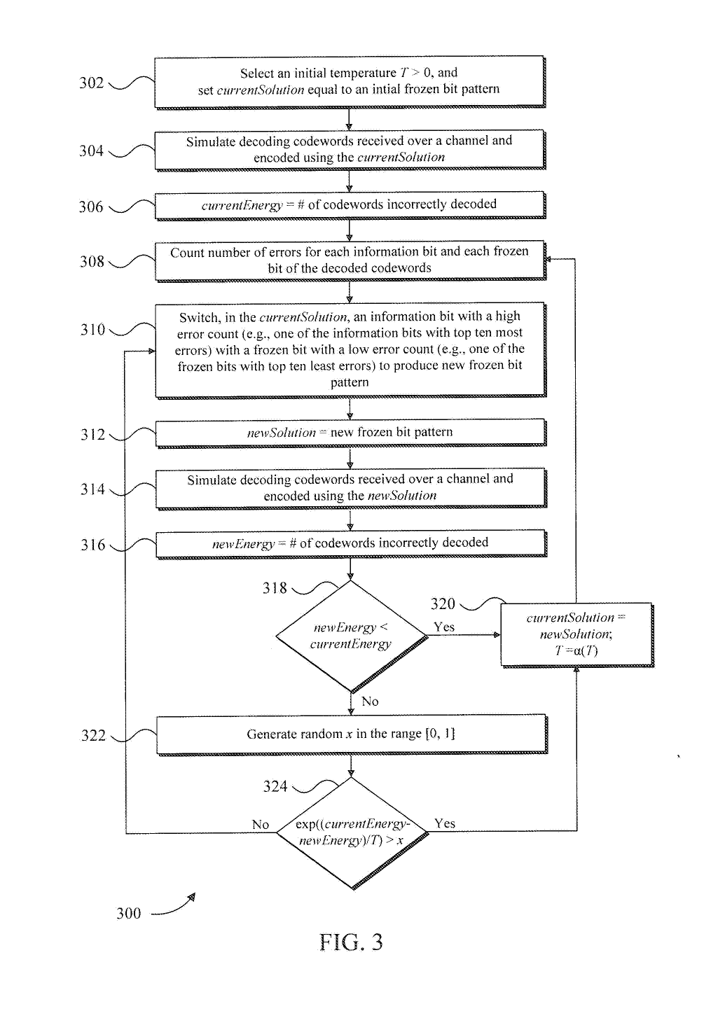

Referring now to FIG. 3, a flowchart 300 of an example simulated annealing based method for determining a good frozen bit pattern in accordance with embodiments of the present disclosure is illustrated. Flowchart 300 can be implemented in hardware, software, or any combination thereof to find a frozen bit pattern that provides good decoding performance for different types of channels, including an AWGN channel.

Simulated annealing is an algorithm that is based on the annealing process used to make materials (often metal) more ductile. Annealing involves heating a material to alter its physical properties (e.g., by bending the material) and then slowly letting the material cool. The heat increases that rate at which atoms of the material can move to redistribute and destroy dislocations in the material, allowing the material to retain its new physical properties without major defects.

Simulated annealing works in much the same way. In simulated annealing, a temperature variable is maintained and initially set to a high temperature. The temperature variable is then slowly reduced in accordance with a temperature reduction function. While the temperature variable is high, the algorithm allows solutions to a problem that are worse than a currently best solution to the problem to be accepted. This allows the algorithm to escape local optimums to (ideally) find better solutions. As the temperature is reduced, the likelihood of accepting a solution that is worse than the current best solution is also reduced. The gradual cooling process is an effective mechanism of finding a good solution to a large problem that has numerous local optimums.

In FIG. 3, simulated annealing is used to find a good solution to the problem of finding a frozen bit pattern for a polar code with a given block length and code rate. The criteria used by the method to determine whether a frozen bit pattern is good or not is, in general, the number of information vectors u that are incorrectly decoded at a simulated receiver using the frozen bit pattern.

The method of flowchart 300 begins at step 302, where a temperature variable T is initially set to a high temperature and a variable currentSolution is set equal to an initial frozen bit pattern. The variable currentSolution retains the currently best frozen bit pattern through the execution of the method of flowchart 300.

After step 302, the method of flowchart 300 proceeds to step 304. Step 304 includes decoding of codewords received over a simulated channel, where the codewords have been encoded using the currentSolution. The channel used for simulation purposes can be any type of channel, including an AWGN channel, with adjustable noise parameters.

After step 304, the method of flowchart 300 proceeds to step 306, where the variable currentEnergy is set equal to the number of codewords incorrectly decoded at step 304 or a number based on the number of codewords decoded incorrectly at step 304. As mentioned above, the number of codewords incorrectly decoded is used to determine whether a frozen bit pattern is good or not.

After step 306, the method of flowchart 300 proceeds to step 308, where the number of errors for each information bit and each frozen bit of the decoded codewords are counted and maintained as separate values. For example, assuming an (8, 4) polar code, there are four information bits and four frozen bits. After decoding a codeword incorrectly, the error count for an information bit or frozen bit that is decoded in error can be incremented. It should be noted that, during normal decoding of a polar encoded codeword, the frozen bits are not decoded given that they are known a priori at the receiver. But for purposes of determining a good frozen bit pattern, the frozen bits are decoded during the execution of the method of flowchart 300. It should be further noted that, in other embodiments, the number of errors does not have to be counted for each information bit and each frozen bit of the decoded code words.

After step 308, the method of flowchart 300 proceeds to step 310, where an information bit with a high error count (e.g., one of the information bits with the top ten most errors or the information bit with the highest error count as determined in the previous step) is switched with a frozen bit with a low error count (e.g., one of the frozen bits with the top ten lowest error counts as determined in the previous step) to produce a new frozen bit pattern. Switching an information bit with a frozen bit means that the bit index corresponding to the information bit becomes a frozen bit and the bit index corresponding to the frozen bit becomes an information bit. It should be noted that, in other embodiments, more than one information bit with a high error count can be switched with a frozen bit with a low error count to produce a new frozen bit pattern during step 308.

After step 310, the method of flowchart 300 proceeds to step 312 and the variable newSolution is set equal to the new frozen bit pattern produced in step 310.

After step 312, the method of flowchart 300 proceeds to step 314. Step 314 includes decoding of codewords received over a simulated channel, where the codewords are encoded using the newSolution. The channel used for simulation purposes generally will be the same channel with the same noise parameters used in step 304.

After step 314, the method of flowchart 300 proceeds to step 316, where the variable newEnergy is set equal to the number of codewords incorrectly decoded at step 314 or a number based on the number of codewords decoded incorrectly at step 314. As mentioned above, the number of codewords incorrectly decoded is used to determine whether a frozen bit pattern is good or not.

After step 316, the method of flowchart 300 proceeds to step 318, where the newEnergy is compared to the currentEnergy to determine whether the newSolution is better than the currentSolution. If the newEnergy is less than the currentEnergy, meaning that less codewords were decoded incorrectly using the new frozen bit pattern, then the method of flowchart 300 proceeds to step 320; otherwise, the method of flowchart 300 proceeds to step 322.

Assuming that the newEnergy is less than the currentEnergy, flowchart 300 proceeds to step 320. At step 320, the newSolution is accepted as the current best frozen bit pattern by setting the currentSolution equal to the newSolution. In addition, at step 320, the current temperature is reduced according to a temperature reduction function α(T). Although not shown, before the method of flowchart 300 proceeds back to step 308 from step 320 as shown in FIG. 3, a stopping criteria for the method of flowchart 300 can be checked. For example, the stopping criteria can include a maximum iteration count that stops the method of flowchart 300 after so many iterations or based on the number of codewords decoded incorrectly for the currentSolution being below a predetermined value. Other stopping criteria can include the temperature T being below a predetermined value, for example.

Referring back to step 318, assuming now that the newEnergy is not less than the currentEnergy, implying that the newSolution is a worse solution than the currentSolution, the method of flowchart 300 proceeds to step 322. At step 322, a random variable x is generated in the range of [0, 1].

After step 322, the method of flowchart 300 proceeds to step 324. At step 324, an exponential function is evaluated based on the difference between the newEnergy and the currentEnergy divided by the temperature T. The resulting value of the exponential function is then compared to the random variable x generated at step 318. If the resulting value is greater than the random variable x, then the method of flowchart 300 proceeds to step 320 and the newSolution is accepted as the current best frozen bit pattern despite being a worse solution) by setting the currentSolution equal to the newSolution. Otherwise, flowchart 300 proceeds back to step 310 to switch a different information bit and frozen bit than was switched during the last iteration to (ideally) find a better frozen bit pattern than the currentSolution. In general, the smaller the difference between the newEnergy and the currentEnergy and the higher the temperature T, the more likely the method of flowchart 300 proceeds to step 320 and the newSolution is accepted as the current best frozen bit pattern despite being a worse solution than the currentSolution.

It should be noted that, before the method of flowchart 300 proceeds back to step 310 from step 324, a stopping criteria for the method of flowchart 300 can be checked. For example, the stopping criteria can include a maximum iteration count that stops the method of flowchart 300 after so many iterations. Other stopping criteria can include the temperature T being below a predetermined value, for example. After the method of flowchart 300 ends, the currentSolution can be used as a good frozen bit pattern.

It should be further noted that steps 322 and 324 can be replaced by other steps that allow a newSolution that is worse than a currentSolution to be accepted as the current best frozen bit pattern with a frequency proportional to the temperate T.

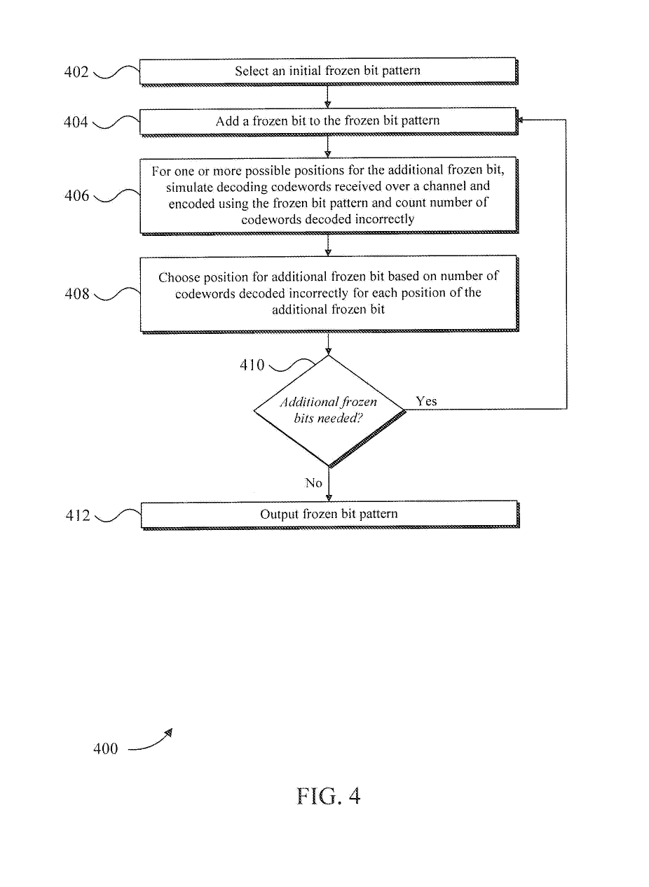

Referring now to FIG. 4, a flowchart 400 of an example hill-climbing based method for determining a good frozen bit pattern in accordance with embodiments of the present disclosure is illustrated. Flowchart 400 can be implemented in hardware, software, or any combination thereof to find a frozen bit pattern that provides good decoding performance for different types of channels, including an AWGN channel, in a reasonable amount of time.

The method of flowchart 400 begins at step 402, where an initial, partial frozen bit pattern is selected for given block length and code rate. The frozen bit pattern can include one or more frozen bits less than (1-code rate)*(block length). In one embodiment, the initial frozen bit pattern used is a good frozen bit pattern determined for a polar code with a smaller block length than the current frozen bit pattern being determined by the method of flowchart 400 but that has the same code rate. A “good” frozen bit pattern can be defined, for example, based on whether the frozen bit pattern provides a coding gain above some predetermined threshold amount.

After step 402, the method of flowchart 400 proceeds to step 404. At step 404, a frozen bit is added to the frozen bit pattern. In one embodiment, more than one frozen bit is added to the frozen bit pattern at step 404.

After step 404, the method of flowchart 400 proceeds to step 406. At step 406, for one or more possible positions for the additional frozen bit (or bits) added at step 404, codewords received over a simulated channel and encoded using the frozen bit pattern are decoded and the number of codewords decoded incorrectly are counted. The channel used for simulation purposes can be any type of channel, including an AWGN channel, with adjustable noise parameters.

After step 406, the method of flowchart 400 proceeds to step 408. At step 408, a position is chosen for each additional frozen bit added at step 404 based on the number of codewords decoded incorrectly for each position of the additional frozen bit simulated at step 406. For example, the position chosen for each additional frozen bit added at step 404 can be selected to be the position which results in the least number of decoding errors at step 406.

After step 408, the method of flowchart 400 proceeds to step 410. At step 410, a determination is made as to whether additional frozen bits need to be added to the current frozen bit pattern. For example, if the number of frozen bits in the current frozen bit pattern is less than (1-code rate)*(block length), the method of flowchart 400 can proceed back to step 404. Otherwise, the current frozen bit pattern can be output at step 412.

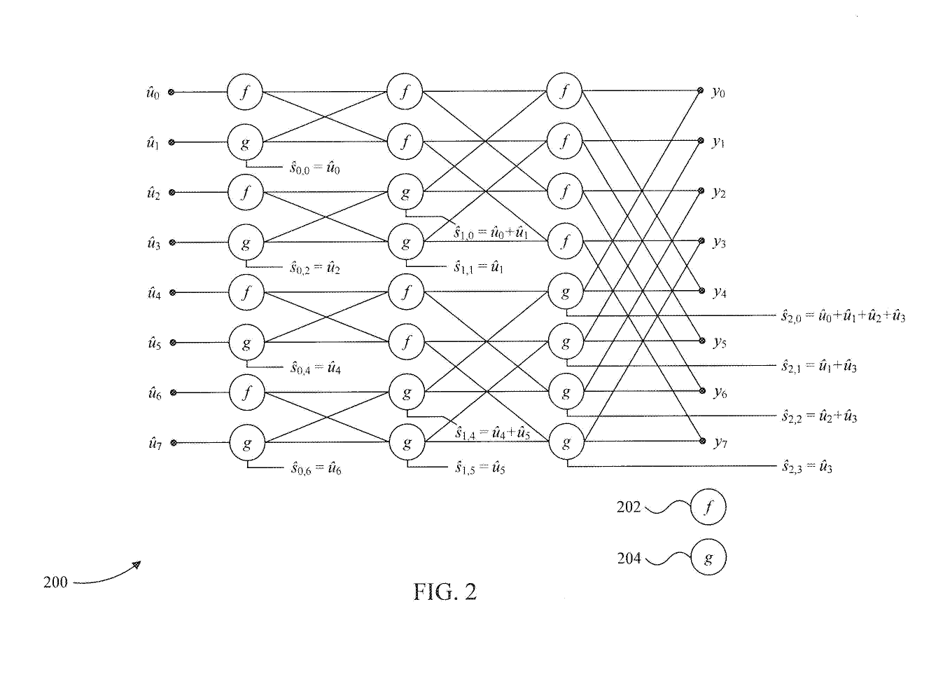

It should be noted that, for either method shown in the flowcharts of FIGS. 3 and 4, the decoder used for decoding codewords sent over the simulated channel can be a successive-cancellation decoder, as described above in FIG. 2, or a belief propagation decoder, which is described below. In one embodiment, a successive-cancellation decoder is used, even if the polar code to be determined by the methods shown in the flowcharts of FIGS. 3 and 4 is to be used in a belief propagation decoder. This is because the landscape of possible frozen bit pattern solutions for a successive cancellation decoder turns out to be more smooth than the landscape of frozen bit pattern solutions for a belief propagation decoder, which means that the landscape of possible frozen bit pattern solutions for a successive cancellation decoder has less local optimums.

### III. TRELLIS-BASED FROZEN BIT PATTERN CONVERSION

As mentioned above, polar decoding is conventionally performed using the successive cancellation decoding algorithm. In general, the successive cancellation decoding algorithm can be implemented with O(N log N) complexity, but due to the inherent data dependencies in the algorithm, very little parallelization can be exploited in implementing the algorithm. As a result, successive cancellation decoders, such as decoder 200 in FIG. 2, suffer from low decoding throughput and high latency.

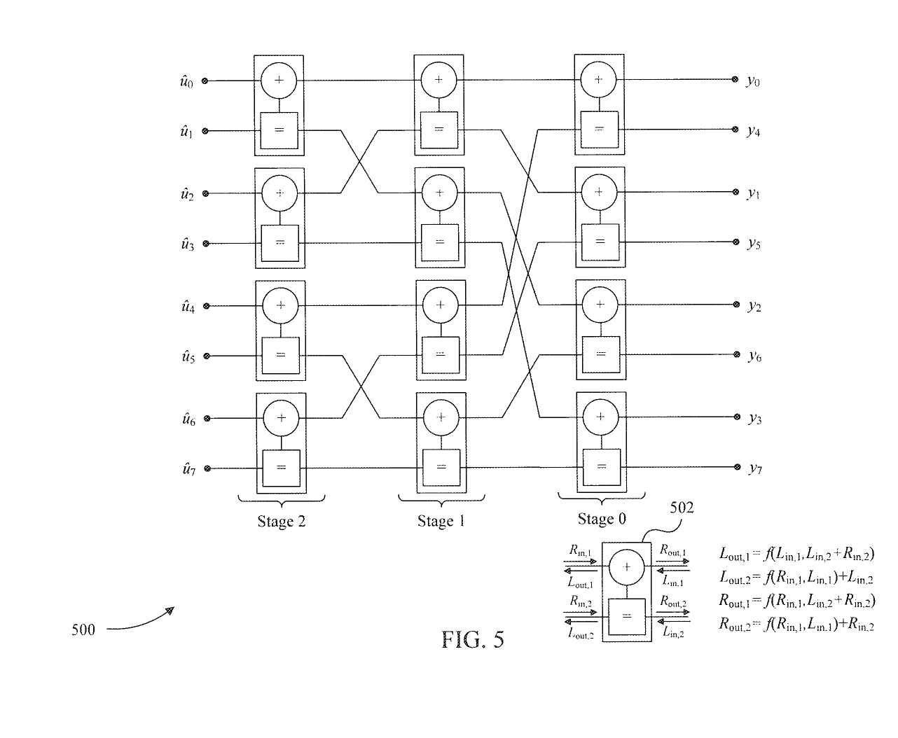

Belief propagation decoding is another decoding algorithm that can be used to decode polar encoded codewords. Belief propagation decoding can achieve a higher throughput than successive cancellation decoding, while providing similar or better decoding performance in terms of error rate. FIG. 5 illustrates an example belief propagation decoder 500 for a block length N=8. Like the successive cancellation decoder, the belief propagation decoder 500 in FIG. 5 is based on the factor graph representation of the transform F₂^{⊕n} and therefore has as a Kronecker-based trellis decoder structure.

Belief propagation decoder 500 is made up of three stages of processing elements 502. Each processing element 502 has four input/output nodes and each of these nodes is associated with two types of probability messages: left-to-right probability messages and right-to-left probability messages. Both types of messages are propagated and updated iteratively between adjacent nodes during execution of the belief propagation decoding process. L_{out,1} and L_{out,2} are the right-to-left probability messages generated by element 502 and passed as output, and R_{out,1} and R_{out,2} are the left-to-right probability messages generated by element 502. R_{in,1} and R_{in,2} are the right-to-left probability messages received by processing element 502, and L_{in,1} and L_{in,2} are the left-to-right probability messages received by element 502. It should be noted that processing elements 502 can be combined into higher-radix processing elements (e.g., processing elements with 8 input/output nodes).

The probability message update equations are shown in the bottom right of FIG. 5, where the function ƒ is defined as follows:

$$f ( {l}_{a} , {l}_{b} ) = \frac{1 + {l}_{a} \cdot {l}_{b}}{{l}_{a} + {l}_{b}} \qquad ( 4 )$$

It will be appreciated that an equivalent function can be derived in the logarithmic domain and performed by processing element 502. It will be further appreciated that the equivalent function performed by processing element 502 can be further simplified through the use of the min-sum approximation used in LDPC decoding.

During operation, probability messages first propagate from the right most nodes, where the vector y is received, to the left most nodes, where the estimated vector û is provided. After the messages arrive at the left most nodes, the message direction is reversed and the messages will propagate back towards the right most nodes, completing one iteration of the belief propagation decoding process. After some number of iterations, belief propagation decoder 500 outputs the decoded vector û.

Although belief propagation decoders, such as belief propagation decoder 500, can provide a higher throughput than successive cancellation decoders, belief propagation decoders still suffer from high memory and complexity requirements. To reduce the memory and complexity requirements, one or more stages of processing elements 502 (or portions of one or more stages of processing elements 502) can be time-multiplexed. However, as shown in exemplary belief propagation decoder 500, the routing structure between each stage of processing elements is different. Thus, in order to time-multiplex one or more stages of processing elements 502 (or portions of one or more stages of processing elements 502) a reconfigurable routing structure will be needed.

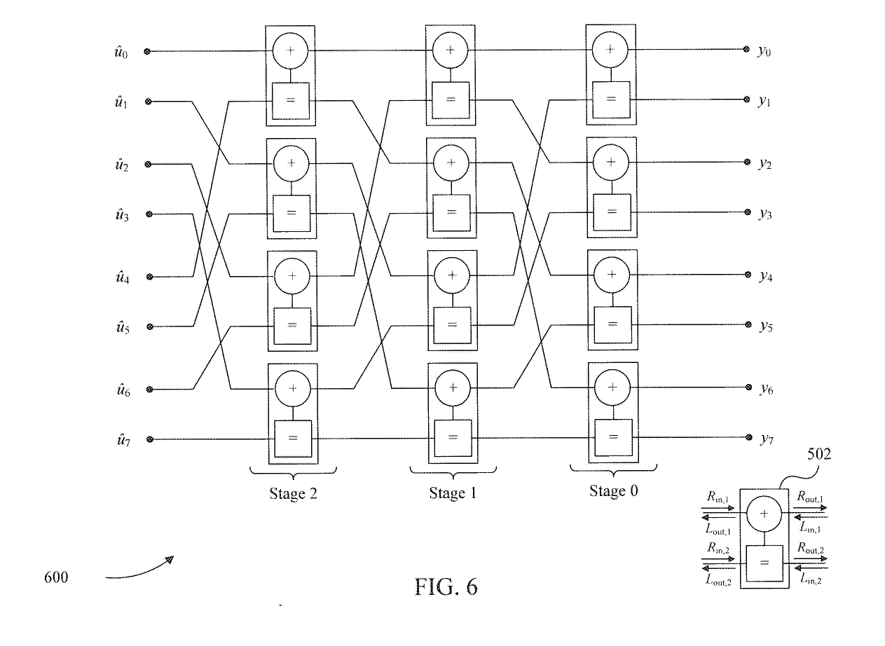

One solution to this issue is to reorganize the Kronecker-based trellis structure of the belief propagation decoder to have the same routing structure between stages of processing elements, or at least between those processing elements to be time-multiplexed. One such reconfiguration 600 is shown in FIG. 6 for belief propagation decoder 500. Further details on this reorganization can be found in E. Ankan, “Polar codes: A pipelined implementation,” Proc. Int. Symp. Broadband Communication, (ISBC2010), 11-14 Jul. 2010, Melaka, Malaysia, which is incorporated herein by reference. Because the routing structure between stages is identical, no reconfigurable routing structure is needed in order to time-multiplex one or more stages of processing elements 502 (or portions of one or more stages of processing elements 502).

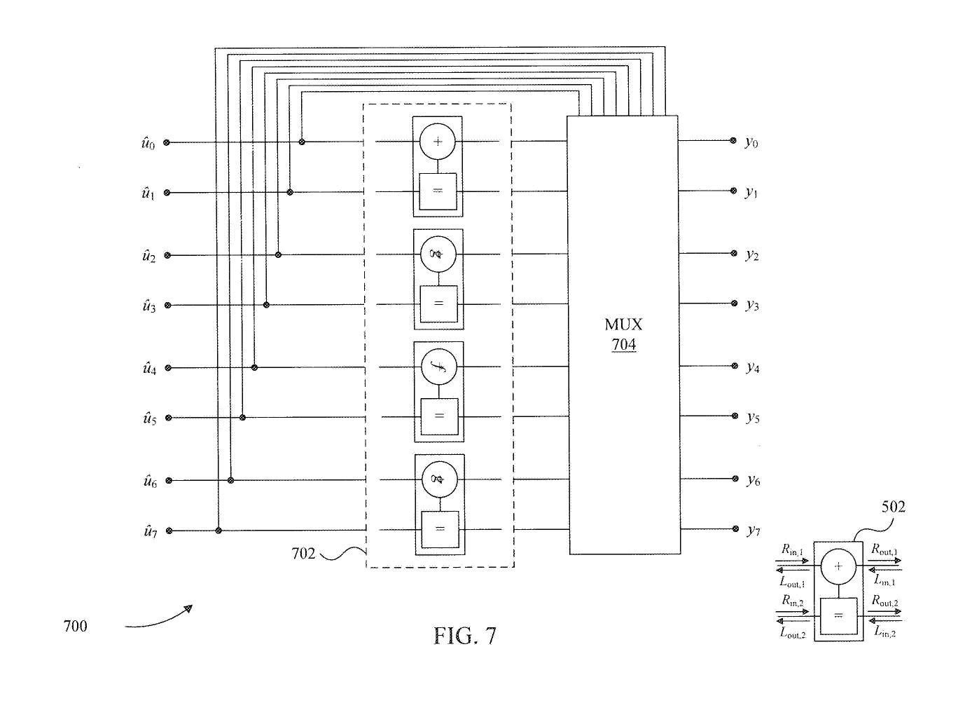

Referring now to FIG. 7, a belief propagation decoder 700 with a time-multiplexed stage of processing elements 702 is shown for a block length N=8. The multiplexer 704 is used to multiplex between the input vector y and the intermediate messages passed between processing elements during different processing steps of the decoding process. Although not shown in FIG. 7, a memory can be used to store intermediate messages produced during one of more of the processing steps of the decoding process. For example, a memory can be placed on either side of processing elements 702 or even on both sides of processing elements 702 to store intermediate messages produced during one or more of the processing steps.

One issue with reconfiguring the Kronecker-based trellis structure to have the same routing structure between stages of processing elements is that there is a degradation in the performance of the decoder with the reconfigured structure when using the same frozen-bit pattern determined for the Kronecker-based trellis structure.

To fix this drop in decoder performance, the frozen-bit pattern determined for the Kronecker-based trellis structure (such as one determined using the methods described above in regard to FIGS. 3 and 4) can be converted by determining a new bit position or bit index for each bit in the frozen bit pattern. More specifically, a new bit position or bit index for each bit in the frozen bit pattern can be determined by (1) converting the decimal representation of the bit index into its binary representation; (2) reversing the bit-order of the binary representation, and (3) converting the reversed bit-order binary representation back into decimal form to provide the new bit-index.

For example, the frozen bit pattern (1⁷0⁶0⁵1⁴1³0²0¹1⁰) has eight bits and therefore eight bit indices 0-7, each of which is shown to the upper-right of its corresponding bit in the frozen bit pattern. To convert this frozen bit pattern into one that works well for the reconfigured trellis structure, a new bit position or bit index for each bit in the frozen bit pattern can be determined using the three steps outlined above. For example, (1) converting bit index 0 into its binary representation results in ‘000’; (2) reversing the bit-order of the binary representation ‘000’ results in the same binary sequence ‘000’; and (3) converting the reversed bit-order binary representation back into decimal form results in the new bit-index 0, which turns out to be the same as the original bit index. Thus, the bit at bit-index 0 of the original frozen bit pattern, which is ‘1’ in the example frozen bit pattern given above, will remain at bit position 0 in the converted frozen bit pattern.

Continuing with the above example, (1) converting bit index 1 into its binary representation results in ‘001’; (2) reversing the bit-order of the binary representation ‘001’ results in the binary sequence ‘100’; and (3) converting the reversed bit-order binary representation back into decimal form results in the new bit-index 4. Thus, the bit at bit-index 1 of the original frozen bit pattern, which is ‘0’ in the example frozen bit pattern given above, will be repositioned to bit index 4 in the converted frozen bit pattern.

It can be shown that the final converted frozen bit pattern for the example frozen bit pattern (10011001) given above will be (11000011). Assuming the original frozen bit pattern was a good frozen bit pattern for the Kronecker-based trellis decoding structure, the converted frozen bit pattern will also provide a good decoding performance for the reconfigured decoder structure.

Although the above method can be used to convert a frozen bit pattern for a Kronecker based trellis structure to a frozen bit pattern for a reconfigured decoder structure that has the same routing structure between stages of processing elements, a more general conversion method can be used to convert any frozen bit pattern determined for one decoder trellis structure to a frozen bit pattern for another decoder trellis structure. In particular, a polar decoder trellis includes two different operations: f and g functions for a successive cancellation based polar decoder trellis, and the two probability message update functions respectively performed for a given message direction by the + and = modules graphically depicted in element 502 of FIG. 5. The general frozen bit pattern conversion method includes repositioning each frozen bit in an original frozen bit pattern determined for one trellis decoder such that it “sees” the same series of f and g functions or the same series of probability message update functions as it did before in the new trellis structure.

For example, assuming bit û₁ is a frozen bit in a given frozen bit pattern for the decoder trellis of FIG. 5, to convert the given frozen bit pattern to one that will work well for the different decoder trellis of FIG. 6, the frozen bit at û₁ in FIG. 5 is repositioned to bit û₄ in FIG. 6, which “sees” the same series of + and = modules (i.e., the series “=”, “+”, “+”) going from left to right through the trellis as û₁ in FIG. 5.

Because of the described close relation between frozen-bit pattern selection and underlying Trellis structure, Polar-code specifications in general can incorporate both a frozen-bit-pattern specification and a specification of the Trellis structure related to the frozen-bit-pattern specification.

### IV. EXAMPLE COMPUTER SYSTEM ENVIRONMENT

It will be apparent to persons skilled in the relevant art(s) that various elements and features of the present disclosure, as described herein, can be implemented in hardware using analog and/or digital circuits, in software, through the execution of instructions by one or more general purpose or special-purpose processors, or as a combination of hardware and software.

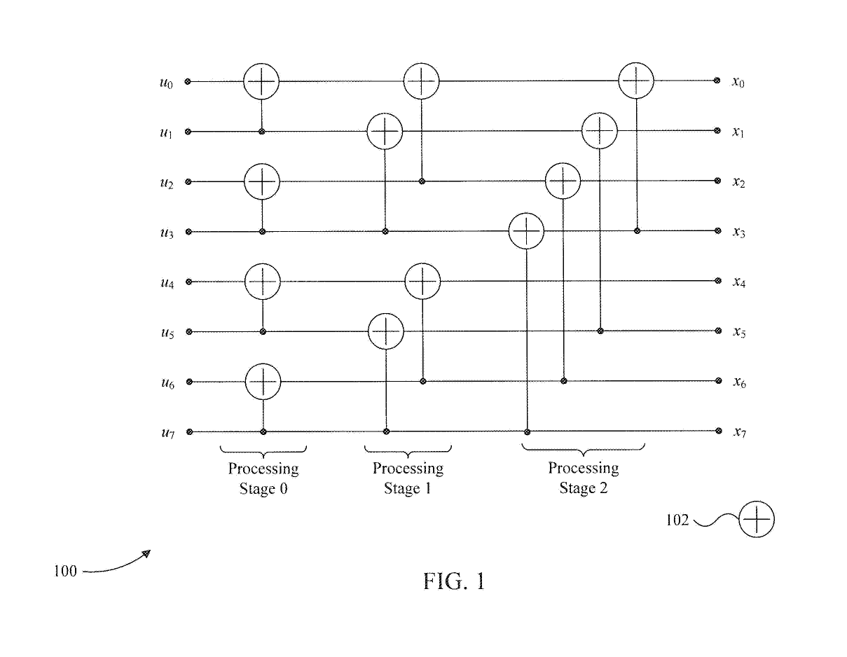

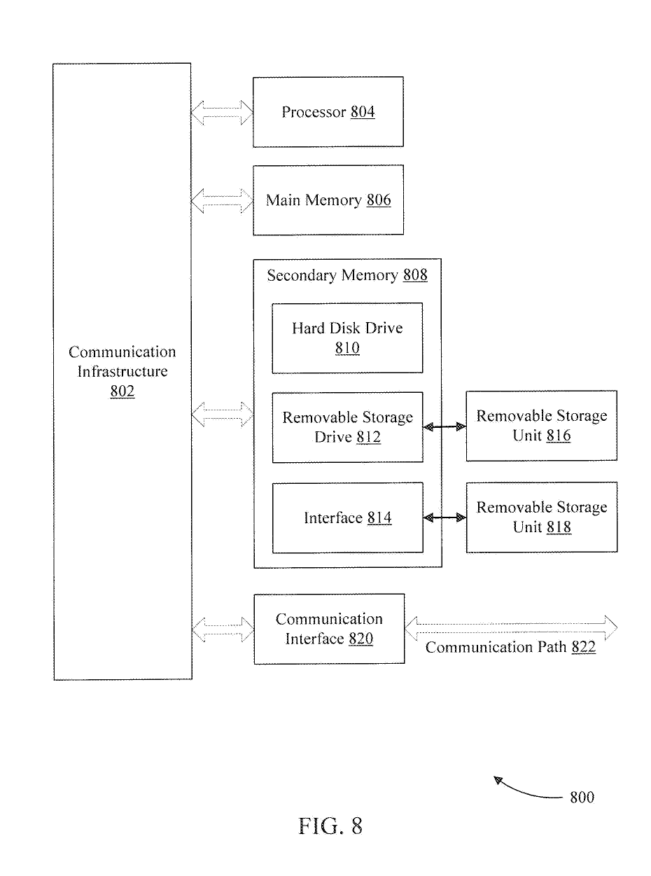

The following description of a general purpose computer system is provided for the sake of completeness. Embodiments of the present disclosure can be implemented in hardware, or as a combination of software and hardware. Consequently, embodiments of the disclosure may be implemented in the environment of a computer system or other processing system. An example of such a computer system 800 is shown in FIG. 8. Modules depicted in FIGS. 1, 2, and 5-7 may execute on one or more computer systems 800. Furthermore, each of the steps of the methods depicted in FIGS. 3 and 4 can be implemented on one or more computer systems 800.

Computer system 800 includes one or more processors, such as processor 804. Processor 804 can be a special purpose or a general purpose digital signal processor. Processor 804 is connected to a communication infrastructure 802 (for example, a bus or network). Various software implementations are described in terms of this exemplary computer system. After reading this description, it will become apparent to a person skilled in the relevant art(s) how to implement the disclosure using other computer systems and/or computer architectures.

Computer system 800 also includes a main memory 806, preferably random access memory (RAM), and may also include a secondary memory 808. Secondary memory 808 may include, for example, a hard disk drive 810 and/or a removable storage drive 812, representing a floppy disk drive, a magnetic tape drive, an optical disk drive, or the like. Removable storage drive 812 reads from and/or writes to a removable storage unit 816 in a well-known manner. Removable storage unit 816 represents a floppy disk, magnetic tape, optical disk, or the like, which is read by and written to by removable storage drive 812. As will be appreciated by persons skilled in the relevant art(s), removable storage unit 816 includes a computer usable storage medium having stored therein computer software and/or data.

In alternative implementations, secondary memory 808 may include other similar means for allowing computer programs or other instructions to be loaded into computer system 800. Such means may include, for example, a removable storage unit 818 and an interface 814. Examples of such means may include a program cartridge and cartridge interface (such as that found in video game devices), a removable memory chip (such as an EPROM, or PROM) and associated socket, a thumb drive and USB port, and other removable storage units 818 and interfaces 814 which allow software and data to be transferred from removable storage unit 818 to computer system 800.

Computer system 800 may also include a communications interface 820. Communications interface 820 allows software and data to be transferred between computer system 800 and external devices. Examples of communications interface 820 may include a modem, a network interface (such as an Ethernet card), a communications port, a PCMCIA slot and card, etc. Software and data transferred via communications interface 820 are in the form of signals which may be electronic, electromagnetic, optical, or other signals capable of being received by communications interface 820. These signals are provided to communications interface 820 via a communications path 822. Communications path 822 carries signals and may be implemented using wire or cable, fiber optics, a phone line, a cellular phone link, an RF link and other communications channels.

As used herein, the terms “computer program medium” and “computer readable medium” are used to generally refer to tangible storage media such as removable storage units 816 and 818 or a hard disk installed in hard disk drive 810. These computer program products are means for providing software to computer system 800.

Computer programs (also called computer control logic) are stored in main memory 806 and/or secondary memory 808. Computer programs may also be received via communications interface 820. Such computer programs, when executed, enable the computer system 800 to implement the present disclosure as discussed herein. In particular, the computer programs, when executed, enable processor 804 to implement the processes of the present disclosure, such as any of the methods described herein. Accordingly, such computer programs represent controllers of the computer system 800. Where the disclosure is implemented using software, the software may be stored in a computer program product and loaded into computer system 800 using removable storage drive 812, interface 814, or communications interface 820.

In another embodiment, features of the disclosure are implemented primarily in hardware using, for example, hardware components such as application-specific integrated circuits (ASICs) and gate arrays. Implementation of a hardware state machine so as to perform the functions described herein will also be apparent to persons skilled in the relevant art(s).

### V. CONCLUSION

Embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

What is claimed is:

1. A polar decoder comprising:
a plurality of inputs configured to receive a vector y corresponding to a polar encoded codeword;
a plurality of processing elements configured to be time multiplexed over a plurality of steps of a decoding process to decode the vector y into a vector û; and
a plurality of outputs configured to output the vector û, wherein select bits of the vector û are frozen in accordance with a frozen bit pattern determined based on a frozen bit pattern derived for a decoder trellis with a different routing structure between each of a plurality of processing stages.

2. The polar decoder of claim 1, wherein each of the plurality of processing elements is configured to perform the following equation:
$$f ( {l}_{a} , {l}_{b} ) = \frac{1 + {l}_{a} \cdot {l}_{b}}{{l}_{a} + {l}_{b}}$$
or equivalent function in the logarithmic domain.

3. The polar decoder of claim 1, wherein each of the plurality of processing elements is configured to receive and process four input values to provide four output values.

4. The polar decoder of claim 1, wherein the plurality of processing elements consist of N/2 processing elements, where N is the length of the vector y corresponding to the polar encoded codeword.

5. The polar decoder of claim 1, wherein the plurality of processing elements are configured to propagate likelihood information during each of the plurality of processing steps from the plurality of inputs to the plurality of outputs or from the plurality of outputs to the plurality of inputs

6. The polar decoder of claim 1, wherein the frozen bit pattern derived for the decoder trellis with the different routing structure between each of the plurality of processing stages is determined using a successive-cancellation decoding algorithm for polar codes.

7. The polar decoder of claim 1, wherein the frozen bit pattern derived for the decoder trellis with the different routing structure between each of the plurality of processing stages is determined for an explicit communication channel.

8. A polar decoder comprising:
a plurality of inputs configured to receive a vector y corresponding to a polar encoded codeword;
a plurality of processing elements configured to be time multiplexed over a plurality of steps of a decoding process to decode the vector y into a vector û; and
a plurality of outputs configured to output the vector û,
wherein select bits of the vector û are frozen in accordance with a frozen bit pattern determined based on a frozen bit pattern derived for a decoder trellis with a different routing structure between each of a plurality of processing stages,
wherein output messages of the plurality of processing elements produced during each of the plurality of steps of the decoding process are feedback to inputs of the processing elements using a fixed routing interconnect.

9. The polar decoder of claim 8, wherein the decoding process is based on a successive cancellation decoding algorithm.

10. The polar decoder of claim 8, wherein each of the plurality of processing elements is configured to perform the following equation:
$$f ( {l}_{a} , {l}_{b} ) = \frac{1 + {l}_{a} \cdot {l}_{b}}{{l}_{a} + {l}_{b}}$$
or equivalent function in the logarithmic domain.

11. The polar decoder of claim 8, wherein each of the plurality of processing elements is configured to receive and process four input values to provide four output values.

12. The polar decoder of claim 8, wherein the plurality of processing elements consist of N/2 processing elements, where N is the length of the vector y corresponding to the polar encoded codeword.

13. The polar decoder of claim 8, wherein the plurality of processing elements are configured to propagate likelihood information during each of the plurality of processing steps from the plurality of inputs to the plurality of outputs or from the plurality of outputs to the plurality of inputs.

14. The polar decoder of claim 8, wherein the frozen bit pattern is determined using a successive-cancellation decoding algorithm for polar codes.

15. The polar decoder of claim 8, wherein the frozen bit pattern is determined for an additive white Gaussian noise channel.

16. A method for performing polar decoding comprising:
receiving a vector y corresponding to a polar encoded codeword;
time multiplexing a plurality of processing elements over a plurality of steps of a decoding process to decode the vector y into a vector û; and
outputting the vector û,
wherein select bits of the vector û are frozen in accordance with a frozen bit pattern determined based on a frozen bit pattern derived for a decoder trellis with a different routing structure between each of a plurality of processing stages.

17. The method of claim 16, wherein each of the plurality of processing elements is configured to perform the following equation:
$$f ( {l}_{a} , {l}_{b} ) = \frac{1 + {l}_{a} \cdot {l}_{b}}{{l}_{a} + {l}_{b}}$$
or equivalent function in the logarithmic domain.

18. The method of claim 16, wherein each of the plurality of processing elements is configured to receive and process four input values to provide four output values.

19. The method of claim 16, wherein the plurality of processing elements consist of N/2 processing elements, where N is the length of the vector y corresponding to the polar encoded codeword.

20. The method of claim 16, wherein the plurality of processing elements are configured to propagate likelihood information, during each of the plurality of processing steps, from the plurality of inputs to the plurality of outputs or from the plurality of outputs to the plurality of inputs.
